(19) United States
(12) Patent Application Publication
(10) Pub. No.: US 2026/0024598 A1
(43) Pub. Date: Jan. 22, 2026

(54) WEAR LEVELING METHOD, MEMORY STORAGE DEVICE AND MEMORY CONTROL CIRCUIT UNIT

(71) Applicant: PHISON ELECTRONICS CORP., Miaoli (TW)

(72) Inventors: Yu-Heng Liu, Hsinchu County (TW); Yu-Siang Yang, New Taipei City (TW); Chia-Cheng Hsu, New Taipei City (TW); An-Cheng Liu, Taipei City (TW); Wei Lin, Taipei City (TW)

(73) Assignee: PHISON ELECTRONICS CORP., Miaoli (TW)

(21) Appl. No.: 18/800,114

(22) Filed: Aug. 11, 2024

(30) Foreign Application Priority Data
Jul. 18, 2024 (TW) 113126989

(51) Int. Cl. G11C 16/34; G11C 16/26

(52) U.S. Cl. CPC G11C 16/349; G11C 16/26; G11C 16/3418

(57) ABSTRACT

A wear leveling method, a memory storage device and a memory control circuit unit are provided. The wear leveling method includes: obtaining an open bit count of each physical erasing unit; determining whether there is a first physical erasing unit with the open bit count greater than a first threshold; and in response to there being the first physical erasing unit with the open bit count greater than the first threshold, performing a first wear leveling operation on the first physical erasing unit.

### CROSS-REFERENCE TO RELATED APPLICATION

This application claims the priority benefit of Taiwan application serial no. 113126989, filed on Jul. 18, 2024. The entirety of the above-mentioned patent application is hereby incorporated by reference herein and made a part of this specification.

### BACKGROUND

### Technical Field

The disclosure relates to a memory management technology, and in particular relates to a wear leveling method, a memory storage device, and a memory control circuit unit.

### Description of Related Art

The rapid growth of portable electronic devices such as mobile phones and laptops in recent years has led to a rapid increase in consumer demand for storage media. Since a rewritable non-volatile memory module (e.g. a flash memory) has the characteristics of data non-volatility, power saving, small size, and having no mechanical structure, it is very suitable for being built in a variety of portable electronic devices as exemplified above.

With the advancement in the field of artificial intelligence (AI) technology, during AI training, rewritable non-volatile memory modules are accessed continuously in a short period of time, significantly shortening the service life of these rewritable non-volatile memory modules. In addition, high program/erase count also causes severe tunneling oxide degradation of memory cells, thereby wearing out the rewritable non-volatile memory module.

Generally speaking, in order to extend the service life of a rewritable non-volatile memory module, a wear leveling method is used to evenly use the physical erasing units in the rewritable non-volatile memory module. Traditional wear leveling methods mostly use the program/erase count and/or the error bit of the physical erasing unit as the basis for implementing the wear leveling method. However, the wear leveling method based on the program/erase count cannot effectively improve the wear condition of the rewritable non-volatile memory module. On the other hand, since the SLC mode is mostly used to access data during AI training, in SLC mode, if the program/erase count is low (e.g., less than 120k times), almost no error bits are generated. Therefore, error bits cannot be used as the basis for implementing the wear leveling method. In addition, if the program/erase count is high (e.g., more than 120k times), the error bit increases rapidly. At this time, the rewritable non-volatile memory module already has a certain degree of wear. Therefore, the wear leveling method based on error bits also cannot effectively improve the wear condition of the rewritable non-volatile memory module.

Based on the above, how to extend the service life of the rewritable non-volatile memory module and address the adverse effects caused by the tunneling oxide degradation are urgent problems that those skilled in the art are eager to solve.

### SUMMARY

A wear leveling method, a memory storage device, and a memory control circuit unit, which may provide a staged wear leveling operation, are provided in the disclosure. When performing wear leveling operations, the degree of wear of the rewritable non-volatile memory module is taken into consideration. This approach prevents severe wear of the rewritable non-volatile memory module and extends its service life.

The wear leveling method includes the following operation. An open bit count of each of the physical erasing units are obtained. Whether there is a first physical erasing unit with the open bit count greater than a first threshold is determined. In response to there being the first physical erasing unit with the open bit count greater than the first threshold, a first wear leveling operation is performed on the first physical erasing unit.

In an exemplary embodiment of the disclosure, obtaining the open bit count of each of the physical erasing units includes the following operation. A status read operation is performed on each of the physical erasing units to obtain the open bit count.

In an exemplary embodiment of the disclosure, performing the status read operation includes the following operation. A read voltage is applied to multiple memory cells in each of the physical erasing units in a writing state to obtain the open bit count.

In an exemplary embodiment of the disclosure, an error detecting and correcting operation is not performed during a process of performing the status read operation.

In an exemplary embodiment of the disclosure, the wear leveling method further includes the following operation. An average program/erase count of the physical erasing units are obtained. Whether the average program/erase count is greater than a switching threshold is determined. In response to the average program/erase count not being greater than the switching threshold, a second wear leveling operation is performed based on a program/erase count of each of the physical erasing units.

In an exemplary embodiment of the disclosure, the wear leveling method further includes the following operation. In response to the average program/erase count being greater than the switching threshold, the first wear leveling operation is performed based on the open bit count of each of the physical erasing units.

In an exemplary embodiment of the disclosure, the wear leveling method further includes the following operation. In response to the average program/erase count being greater than the switching threshold, the first wear leveling operation is performed based on the program/erase count of each of the physical erasing units and the open bit count of each of the physical erasing units.

In an exemplary embodiment of the disclosure, the open bit count is configured to indicate a degree of wear of each of the physical erasing units.

In an exemplary embodiment of the disclosure, the wear leveling method further includes the following operation. In response to a number of the physical erasing units with the open bit count exceeding a warning threshold being greater than a threshold, a warning signal is output.

An exemplary embodiment of the disclosure further provides a memory storage device, which includes a connection interface unit, a rewritable non-volatile memory module, and a memory control circuit unit. The memory control circuit unit is coupled to the connection interface unit and the rewritable non-volatile memory module. The connection interface unit is configured to couple to a host system. The rewritable non-volatile memory module includes multiple physical erasing units. The memory control circuit unit includes an error detecting and correcting circuit. The memory control circuit unit is configured to obtain open bit count of each of the physical erasing units. The memory control circuit unit is further configured to determine whether there is a first physical erasing unit with the open bit count greater than a first threshold. In response to there being the first physical erasing unit with the open bit count greater than the first threshold, the memory control circuit unit is further configured to perform a first wear leveling operation on the first physical erasing unit.

In an exemplary embodiment of the disclosure, the memory control circuit unit is further configured to perform a status read operation on each of the physical erasing units to obtain the open bit count.

In an exemplary embodiment of the disclosure, the memory control circuit unit is further configured to apply a read voltage to multiple memory cells in each of the physical erasing units in a writing state to obtain the open bit count.

In an exemplary embodiment of the disclosure, the error detecting and correcting circuit does not operate while the memory control circuit unit performs the status read operation.

In an exemplary embodiment of the disclosure, the memory control circuit unit is further configured to obtain an average program/erase count of the physical erasing units. The memory control circuit unit is further configured to determine whether the average program/erase count is greater than a switching threshold. In response to the average program/erase count not being greater than the switching threshold, the memory control circuit unit is further configured to perform a second wear leveling operation based on the program/erase count of each of the physical erasing units.

In an exemplary embodiment of the disclosure, in response to the average program/erase count being greater than the switching threshold, the memory control circuit unit is further configured to perform a first wear leveling operation based on the open bit count of each of the physical erasing units.

In an exemplary embodiment of the disclosure, in response to the average program/erase count being greater than the switching threshold, the memory control circuit unit is further configured to perform a first wear leveling operation based on the program/erase count of each of the physical erasing units and the open bit count of each of the physical erasing units.

In an exemplary embodiment of the disclosure, in response to a number of the physical erasing units with the open bit count exceeding a warning threshold being greater than a threshold, the memory control circuit unit is further configured to output a warning signal.

An exemplary embodiment of the disclosure further provides a memory control circuit unit for controlling a rewritable non-volatile memory module. The rewritable non-volatile memory module includes multiple physical erasing units. The memory control circuit unit includes a host interface, a memory interface, an error detecting and correcting circuit, and a memory management circuit. The memory management circuit is coupled to a host interface, the memory interface, and the error detecting and correcting circuit. The host interface is configured to couple to the host system. The memory interface is configured to couple to a rewritable non-volatile memory module. The memory management circuit is configured to obtain open bit count of each of the physical erasing units. The memory management circuit is further configured to determine whether there is a first physical erasing unit with the open bit count greater than a first threshold. In response to there being the first physical erasing unit with the open bit count greater than the first threshold, the memory management circuit is further configured to perform a first wear leveling operation on the first physical erasing unit.

In an exemplary embodiment of the disclosure, the memory management circuit is further configured to perform a status read operation on each of the physical erasing units to obtain the open bit count.

In an exemplary embodiment of the disclosure, the memory management circuit is further configured to apply a read voltage to multiple memory cells in each of the physical erasing units in a writing state to obtain the open bit count.

In an exemplary embodiment of the disclosure, the error detecting and correcting circuit does not operate while the memory management circuit performs the status read operation.

In an exemplary embodiment of the disclosure, the memory management circuit is further configured to obtain an average program/erase count of the physical erasing units. The memory management circuit is further configured to determine whether the average program/erase count is greater than a switching threshold. In response to the average program/erase count not being greater than the switching threshold, the memory management circuit is further configured to perform a second wear leveling operation based on the program/erase count of each of the physical erasing units.

In an exemplary embodiment of the disclosure, in response to the average program/erase count being greater than the switching threshold, the memory management circuit is further configured to perform a first wear leveling operation based on the open bit count of each of the physical erasing units.

In an exemplary embodiment of the disclosure, in response to the average program/erase count being greater than the switching threshold, the memory management circuit is further configured to perform a first wear leveling operation based on the program/erase count of each of the physical erasing units and the open bit count of each of the physical erasing units.

In an exemplary embodiment of the disclosure, in response to a number of the physical erasing units with the open bit count exceeding a warning threshold being greater than a threshold, the memory management circuit is further configured to output a warning signal.

Based on the above, when the average program/erase count is greater than the switching threshold, that is, in the case of high program/erase count, the wear leveling method, the memory storage device, and the memory control circuit unit of the disclosure perform a first wear leveling operation according to the open bit count configured to indicate the degree of wear of the physical erasing units to avoid severe wear of the physical erasing units in the rewritable non-volatile memory module and extend the service life of the rewritable non-volatile memory module.

### BRIEF DESCRIPTION OF THE DRAWINGS

FIG. 1 is a schematic diagram of a host system, a memory storage device, and an input/output (I/O) device according to an exemplary embodiment of the disclosure.

FIG. 2 is a schematic diagram of a host system, a memory storage device, and an I/O device according to an exemplary embodiment of the disclosure.

FIG. 3 is a schematic diagram of a host system and a memory storage device according to an exemplary embodiment of the disclosure.

FIG. 4 is a schematic diagram of a memory storage device according to an exemplary embodiment of the disclosure.

FIG. 5 is a schematic diagram of a memory control circuit unit according to an exemplary embodiment of the disclosure.

FIG. 6 is a schematic diagram of managing a rewritable non-volatile memory module according to an exemplary embodiment of the disclosure.

FIG. 7 is a flowchart of a wear leveling method according to an exemplary embodiment of the disclosure.

FIG. 8 is a flowchart of a wear leveling method according to an exemplary embodiment of the disclosure.

FIG. 9 is a flowchart of a wear leveling method according to an exemplary embodiment of the disclosure.

### DETAILED DESCRIPTION OF DISCLOSED EMBODIMENTS

In general, a memory storage device (also referred to as a memory storage system) includes a rewritable non-volatile memory module and a controller (also referred to as a control circuit). The memory storage device may be used with a host system so that the host system may write data to or read data from the memory storage device.

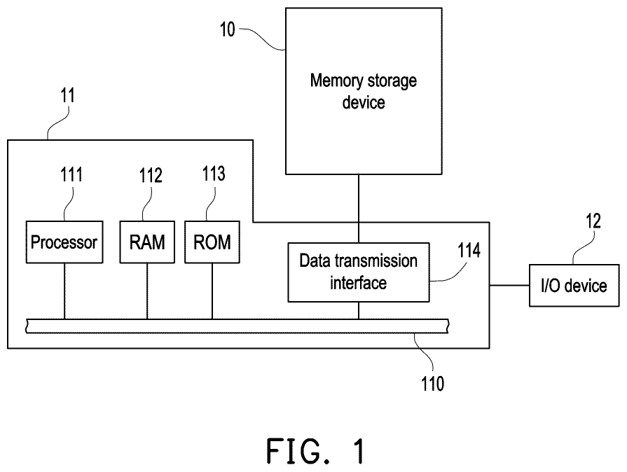

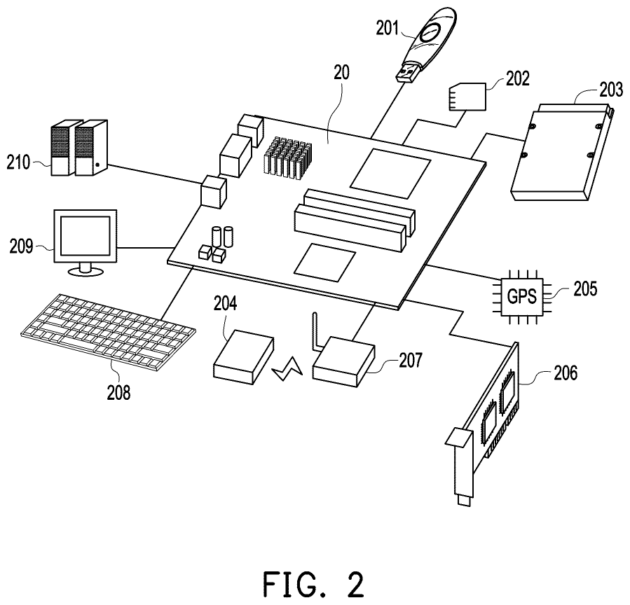

FIG. 1 is a schematic diagram of a host system, a memory storage device, and an input/output (I/O) device according to an exemplary embodiment of the disclosure. FIG. 2 is a schematic diagram of a host system, a memory storage device, and an I/O device according to an exemplary embodiment of the disclosure.

Referring to FIG. 1 and FIG. 2, a host system 11 may include a processor 111, a random access memory (RAM) 112, a read only memory (ROM) 113, and a data transmission interface 114. The processor 111, the random access memory 112, the read only memory 113, and the data transmission interface 114 may be coupled to a system bus 110.

In an exemplary embodiment, the host system 11 may be coupled to a memory storage device 10 through the data transfer interface 114. For example, the host system 11 may store data to or read data from the memory storage device 10 via the data transmission interface 114. In addition, the host system 11 may be coupled to an I/O device 12 through the system bus 110. For example, the host system 11 may transmit output signals to or receive input signals from the I/O device 12 via the system bus 110.

In an exemplary embodiment, the processor 111, the random access memory 112, the read only memory 113, and the data transmission interface 114 may be disposed on a motherboard 20 of the host system 11. The number of the data transmission interface 114 may be one or more. The motherboard 20 may be coupled to the memory storage device 10 through the data transmission interface 114 via a wired or wireless connection.

In an exemplary embodiment, the memory storage device 10 may be, for example, a flash drive 201, a memory card 202, a solid state drive (SSD) 203, or a wireless memory storage device 204. The wireless memory storage device 204 may be a memory storage device based on various wireless communication technologies, such as a near field communication (NFC) memory storage device, a wireless fax (WiFi) memory storage device, a Bluetooth memory storage device, a low power Bluetooth memory storage device (e.g. iBeacon), etc. In addition, the motherboard 20 may also be coupled to various I/O devices, such as a global positioning system (GPS) module 205, a network interface card 206, a wireless transmission device 207, a keyboard 208, a screen 209, a speaker 210, etc., through the system bus 110. For example, in an exemplary embodiment, the motherboard 20 may access the wireless memory storage device 204 through the wireless transmission device 207.

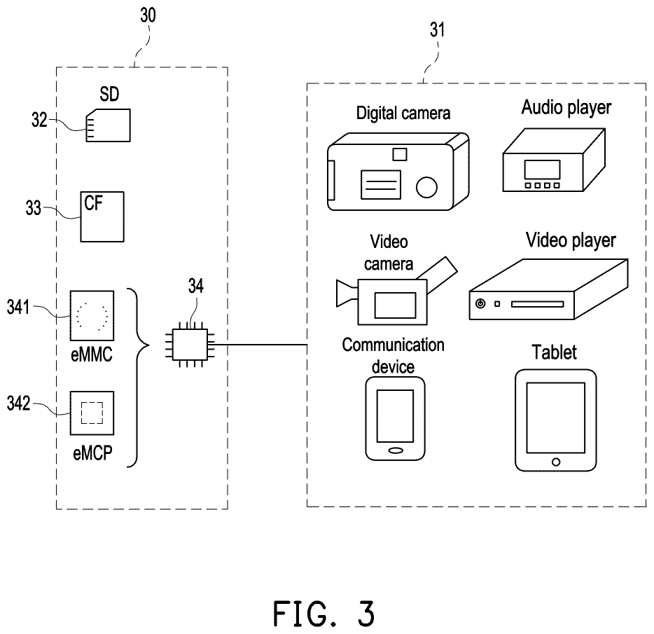

In an exemplary embodiment, the host system 11 is a computer system. In an exemplary embodiment, the host system 11 may be any system that may substantially cooperate with a memory storage device to store data. In an exemplary embodiment, the memory storage device 10 and the host system 11 may respectively include the memory storage device 30 and the host system 31 of FIG. 3.

FIG. 3 is a schematic diagram of a host system and a memory storage device according to an exemplary embodiment of the disclosure. Referring to FIG. 3, the memory storage device 30 may be used in conjunction with the host system 31 to store data. For example, the host system 31 may be a system such a digital camera, a video camera, a communication device, an audio player, a video player, or a tablet, etc. For example, the memory storage device 30 may be various non-volatile memory storage devices, such as a secure digital (SD) card 32, a compact flash (CF) card 33, or an embedded storage device 34, etc., used in the host system 31. The embedded storage device 34 includes various embedded storage devices that directly couple a memory module to a substrate of the host system, such as an embedded multimedia card (eMMC) 341 and/or an embedded multi-chip package (eMCP) storage device 342, etc.

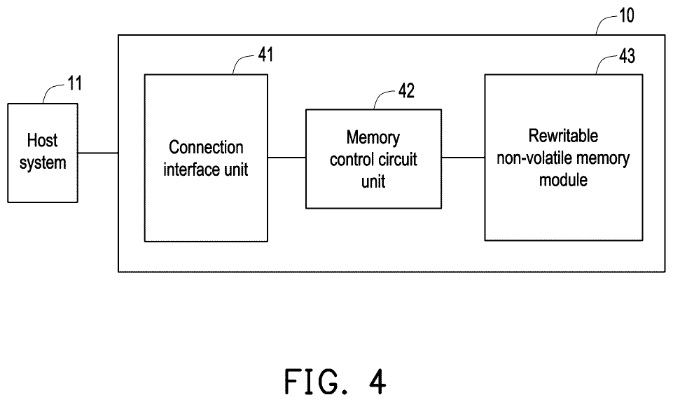

FIG. 4 is a schematic diagram of a memory storage device according to an exemplary embodiment of the disclosure. Referring to FIG. 4, the memory storage device 10 includes a connection interface unit 41, a memory control circuit unit 42, and a rewritable non-volatile memory module 43.

The connection interface unit 41 is configured to couple to a host system 11. The memory storage device 10 may communicate with the host system 11 via the connection interface unit 41. In an exemplary embodiment, the connection interface unit 41 is compatible with the peripheral component interconnect express (PCI Express) standard. In an exemplary embodiment, the connection interface unit 41 may also be compliant to the serial advanced technology attachment (SATA) standard, the parallel advanced technology attachment (PATA) standard, the institute of electrical and electronics engineers (IEEE) 1394 standard, the universal serial bus (USB) standard, the SD interface standard, the ultra high speed-I (UHS-I) interface standard, the ultra high speed-II (UHS-II) interface standard, the memory stick (MS) interface standard, the MCP interface standard, the MMC interface standard, the eMMC interface standard, the universal flash storage (UFS) interface standard, the eMCP interface standard, the CF interface standard, the integrated device electronics (IDE) standard, or other suitable standards. The connection interface unit 41 may be packaged in a chip with the memory control circuit unit 42, or the connection interface unit 41 may be disposed outside a chip including the memory control circuit unit 42.

The memory control circuit unit 42 is coupled to the connection interface unit 41 and the rewritable non-volatile memory module 43. The memory control circuit unit 42 is used to execute multiple logic gates or control commands implemented in a hardware form or a firmware form and to perform operations such as writing, reading, and erasing of data in the rewritable non-volatile memory module 43 according to the commands of the host system 11.

The rewritable non-volatile memory module 43 is used to store the data written by the host system 11. The rewritable non-volatile memory module 43 may include a single level cell (SLC) NAND-type flash memory module (i.e., a flash memory that may store 1 bit in one memory cell), multi-level cell (MLC) NAND-type flash memory module (i.e., a flash memory module that may store 2 bits in one memory cell), a triple level cell (TLC) NAND-type flash memory module (i.e., a flash memory module that may store 3 bits in one memory cell), a quad level cell (QLC)

NAND-type flash memory module (i.e., a flash memory module that may store 4 bits in one memory cell), other flash memory modules, or other memory modules with the same characteristics.

Each memory cell in the rewritable non-volatile memory module 43 stores one or more bits by a change in a voltage (also referred to as a threshold voltage hereinafter). Specifically, there is a charge trapping layer between a control gate and a channel of each of the memory cells. By applying a write voltage (also referred to as a programmed voltage) to the control gate, the amount of electrons in the charge trapping layer may be changed, thereby changing the threshold voltage of the memory cell. This operation of changing the threshold voltage of the memory cell is also referred to as “writing data to the memory cell” or “programming the memory cell”. The threshold voltage may be configured to reflect the data storage status of the memory cell. As the threshold voltage changes, each of the memory cells in the rewritable non-volatile memory module 43 has multiple storage statuses. By applying a read voltage, it is possible to determine which storage status a memory cell belongs to, thereby obtaining the one or more bits stored in the memory cell.

In an exemplary embodiment, the memory cells of the rewritable non-volatile memory module 43 may constitute multiple physical programming units, and the physical programming units may constitute multiple physical erasing units. Specifically, memory cells on the same word line may form one or more physical programming units. If each memory cell may store two or more bits, the physical programming units on the same word line may be classified at least as lower physical programming units and upper physical programming units. For example, the least significant bit (LSB) of a memory cell belongs to a lower physical programming unit, and the most significant bit (MSB) of a memory cell belongs to an upper physical programming unit. Generally, in an MLC NAND flash memory, the write speed of the lower physical programming unit is greater than the write speed of the upper physical programming unit, and/or the reliability of the lower physical programming unit is higher than the reliability of the upper physical programming unit.

In an exemplary embodiment, the physical programming unit is the minimum unit for programming. That is, the physical programming unit is the minimum unit for write data. For example, the physical programming unit may be a physical page or a physical sector. If the physical programming unit is a physical page, then the physical programming unit may include a data bit area and a redundancy bit area. The data bit area includes multiple physical sectors is used for storing user data, and the redundant bit area is used for storing system data (e.g., management data such as error correction codes). In an exemplary embodiment, the data bit area includes 32 physical sectors, and the size of a physical sector is 512 bytes (B). However, in other exemplary embodiments, the data bit area may also include 8, 16, or a greater or lesser number of physical sectors, and the size of each of the physical sectors may also be larger or smaller. On the other hand, the physical erasing unit is the minimum unit for erasing. That is, each of the physical erasing units includes the smallest number of memory cells to be erased together. For example, the physical erasing unit is a physical block.

In an exemplary embodiment, the open bit count of each of the physical erasing units may be obtained by performing a status read operation on each of the physical erasing units of the rewritable non-volatile memory module 43. Specifically, the open bit count of each of the physical erasing units may be obtained by applying a read voltage to the memory cells in the physical programming unit in a writing state (i.e., data is being written or being programmed) of each of the physical erasing units. With the increase in data access operations of memory cells, that is, when the rewritable non-volatile memory module 43 is in the state of high program/erase count, the electrons stored in the charge trapping layer are partially lost to the tunneling oxide layer of the memory cells, resulting in a shift in threshold voltage. By applying a read voltage to the control gate of the memory cell, it is determined whether the threshold voltage of the memory cell is greater than the read voltage. If the threshold voltage of a memory cell is greater than the read voltage, then the memory cell is a memory cell with severe voltage shift, and the bit stored in this memory cell is an open bit. Accordingly, the open bit count of a physical erasing unit may be configured to indicate its degree of wear. That is, the open bit count of all physical erasing units may be configured to indicate the degree of wear of the rewritable non-volatile memory module 43.

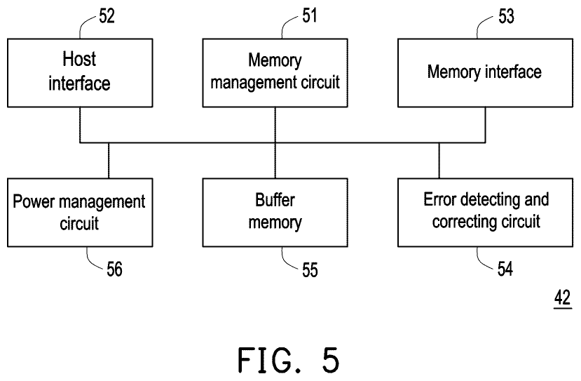

FIG. 5 is a schematic diagram of a memory control circuit unit according to an exemplary embodiment of the disclosure. Referring to FIG. 5, the memory control circuit unit 42 includes a memory management circuit 51, a host interface 52, and a memory interface 53.

The memory management circuit 51 is used to control the overall operation of the memory control circuit unit 42. Specifically, the memory management circuit 51 has multiple control commands, and when the memory storage device 10 operates, the control commands are executed to perform operations such as writing, reading, and erasing data. The following description of the operation of the memory management circuit 51 is equivalent to the description of the operation of the memory control circuit unit 42.

In an exemplary embodiment, the control commands of the memory management circuit 51 are implemented in a firmware form. For example, the memory management circuit 51 has a microprocessor unit (not shown) and a read only memory (not shown), and the control commands are programmed into the read only memory. When the memory storage device 10 operates, the control commands are executed by the microprocessor unit to perform operations such as writing, reading, and erasing data.

In an exemplary embodiment, the control commands of the memory management circuit 51 may also be stored in a specific area of the rewritable non-volatile memory module 43 (for example, a system area dedicated to storing system data in the memory module) in a program code form. In addition, the memory management circuit 51 has a microprocessor unit (not shown), a read-only memory (not shown), and a random access memory (not shown). In particular, the read only memory has a boot code, and when the memory control circuit unit 42 is enabled, the microprocessor unit first executes the boot code to load the control commands stored in the rewritable non-volatile memory module 43 into the random access memory of the memory management circuit 51. Thereafter, the microprocessor unit runs these control commands to perform operations such as writing, reading, and erasing data.

In an exemplary embodiment, the control commands of the memory management circuit 51 may also be implemented in a hardware form. For example, the memory management circuit 51 includes a microcontroller, a memory cell management circuit, a memory writing circuit, a memory reading circuit, a memory erasing circuit, and a data processing circuit. The memory cell management circuit, the memory writing circuit, the memory reading circuit, the memory erasing circuit, and the data processing circuit are coupled to the microcontroller. The memory cell management circuit is used to manage the memory cells or a memory cell group of the rewritable non-volatile memory module 43. The memory writing circuit is used to issue a write command sequence to the rewritable non-volatile memory module 43 to write data into the rewritable non-volatile memory module 43. The memory reading circuit is used to issue a read command sequence to the rewritable non-volatile memory module 43 to read data from the rewritable non-volatile memory module 43. The memory erasing circuit is used to issue an erase command sequence to the rewritable non-volatile memory module 43 to erase data from the rewritable non-volatile memory module 43. The data processing circuit is used to process the data to be written into the rewritable non-volatile memory module 43 and the data read from the rewritable non-volatile memory module 43. The write command sequence, the read command sequence and the erase command sequence may respectively include one or more program codes or command codes for instructing the rewritable non-volatile memory module 43 to perform corresponding writing, reading, and erasing operations. In an exemplary embodiment, the memory management circuit 51 may also issue other types of command sequences to the rewritable non-volatile memory module 43 to instruct the rewritable non-volatile memory module 43 to perform corresponding operations.

The host interface 52 is coupled to the memory management circuit 51. The memory management circuit 51 may communicate with the host system 11 through the host interface 52. The host interface 52 may be used to obtain and identify the commands and data of the host system 11. For example, the commands and data of the host system 11 may be transmitted to the memory management circuit 51 through the host interface 52. In addition, the memory management circuit 51 may transmit data to the host system 11 through the host interface 52. In this exemplary embodiment, the host interface 52 is compatible with the PCI Express standard. However, it should be understood that the disclosure is not limited thereto, and the host interface 52 may also be compatible with the SATA standard, the PATA standard, the IEEE 1394 standard, the USB standard, the SD standard, the UHS-I standard, the UHS-II standard, the MS standard, the MMC standard, the eMMC standard, the UFS standard, the CF standard, the IDE standard, or other suitable data transmission standards.

The memory interface 53 is coupled to the memory management circuit 51 and is used to access the rewritable non-volatile memory module 43. For example, the memory management circuit 51 may access the rewritable non-volatile memory module 43 through the memory interface 53. In other words, the data to be written into the rewritable non-volatile memory module 43 is converted into a format acceptable to the rewritable non-volatile memory module 43 via the memory interface 53. Specifically, if the memory management circuit 51 is to access the rewritable non-volatile memory module 43, the memory interface 53 transmits a corresponding command sequence. For example, the command sequences may include a write command sequence to instruct data writing, a read command sequence to instruct data reading, an erase command sequence to instruct data erasing, and corresponding command sequences for instructing various memory operations (e.g., changing the read voltage level, executing a garbage collection (GC) operation, etc.). These command sequences are, for example, generated by the memory management circuit 51 and transmitted to the rewritable non-volatile memory module 43 via the memory interface 53. These command sequences may include one or more signals or data on the bus. The signals or data may include command codes or program codes. For example, the read command sequence includes information such as the read identification code, the memory address, etc.

In an exemplary embodiment, the memory control circuit unit 42 further includes an error detecting and correcting circuit 54, a buffer memory 55, and a power management circuit 56.

The error detecting and correcting circuit 54 is coupled to the memory management circuit 51 and is configured to execute an error detecting and correcting operation to ensure the correctness of the data. Specifically, when the memory management circuit 51 obtains a write command from the host system 11, the error detecting and correcting circuit 54 generates a corresponding error correcting code (ECC) and/or error detecting code (EDC) for the data corresponding to the write command, and the memory management circuit 51 writes the data corresponding to the write command and the corresponding error correcting code and/or error detecting code to the rewritable non-volatile memory module 43. Thereafter, when the memory management circuit 51 reads data from the rewritable non-volatile memory module 43, it simultaneously reads the error correcting code and/or the error detecting code corresponding to the data, and the error detecting and correcting circuit 54 executes the error detecting and correcting operation on the read data according to the error correcting code and/or error detecting code.

In an exemplary embodiment, the memory management circuit 51 obtains a status read command from the host system 11 and accordingly performs a status read operation on each of the physical erasing units in the rewritable non-volatile memory module 43 to obtain the open bit count of each of the physical erasing units. For example, the memory management circuit 51 may apply a read voltage to the memory cells in the writing state in each of the physical erasing units to obtain the open bit count in each of the physical erasing units. Since the status read operation is used to check the shift state of the threshold voltage of the memory cell, rather than checking whether the read data has errors, during the status read operation, the error detecting and correcting circuit 54 does not operate, that is, the error detecting and correcting circuit 54 does not perform the above-mentioned error detecting and correcting operation. For example, the open bit count of each of the physical erasing units may be configured to indicate the degree of wear of each of the physical erasing units. Therefore, a number of the physical erasing units with the open bit count exceeding a warning threshold is greater than a threshold, it means that the rewritable non-volatile memory module 43 is severely worn out, and the memory management circuit 51 may output a warning signal to notify the user that the rewritable non-volatile memory module 43 has a limited service life. The warning threshold and the threshold may be designed by the user according to actual requirements, and are not limited by the disclosure.

The buffer memory 55 is coupled to the memory management circuit 51 and configured to temporarily store data. The power management circuit 56 is coupled to the memory management circuit 51 and configured to control the power of the memory storage device 10.

In an exemplary embodiment, the rewritable non-volatile memory module 43 of FIG. 4 may include a flash memory module. In an exemplary embodiment, the memory control circuit unit 42 of FIG. 4 may include a flash memory controller. In an exemplary embodiment, the memory management circuit 51 of FIG. 5 may include a flash memory management circuit.

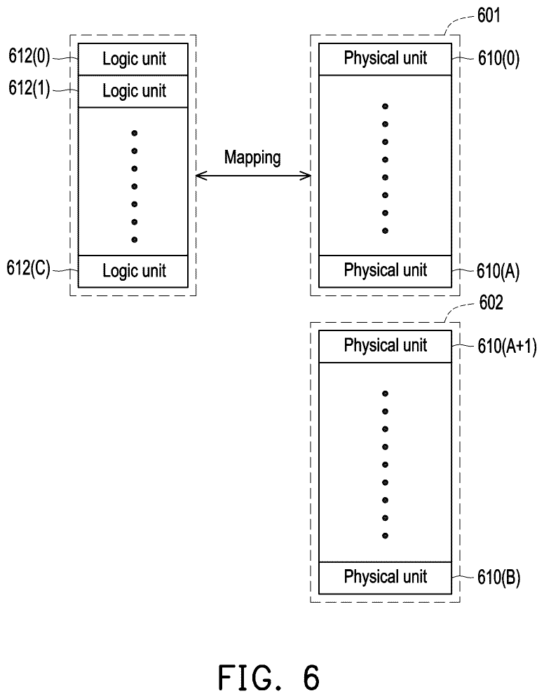

FIG. 6 is a schematic diagram of managing a rewritable non-volatile memory module according to an exemplary embodiment of the disclosure. Referring to FIG. 6, the memory management circuit 51 may logically group the physical units 610(0) to 610(B) in the rewritable non-volatile memory module 43 into a storage area 601 and a spare area 602.

In an exemplary embodiment, a physical unit refers to a physical address or a physical programming unit. In an exemplary embodiment, a physical unit may also be formed by multiple consecutive or non-consecutive physical addresses. In an exemplary embodiment, a physical unit may also refer to a virtual block (VB). A virtual block may include multiple physical addresses or multiple physical programming units. In an exemplary embodiment, a virtual block includes one or more physical erasing units.

The physical units 610(0) to 610(A) in the storage area 601 are configured to store user data (e.g., user data from the host system 11 of FIG. 1). For example, the physical units 610(0) to 610(A) in the storage area 601 may store valid data and invalid data. The physical units 610(A+1) to 610(B) in the spare area 602 do not store data (e.g., valid data). For example, if a certain physical unit does not store valid data, this physical unit may be associated (or added) to the spare area 602. In addition, the physical units in the spare area 602 (or the physical units not storing valid data) may be erased. When new data is written, one or more physical units may be extracted from the spare area 602 to store the new data. In an exemplary embodiment, the spare area 602 is also referred to as a free pool.

The logic units 612(0) to 612(C) may be configured in the memory management circuit 51 to map the physical units 610(0) to 610(A) in the storage area 601. In an exemplary embodiment, each of the logical units corresponds to a logical address. For example, a logical address may include one or more logical block addresses (LBA) or other logical management units. In an exemplary embodiment, a logical unit may also correspond to a logical programming unit or be formed by multiple consecutive or non-consecutive logical addresses.

It should be noted that a logical unit may be mapped to one or more physical units. If a certain physical unit is currently mapped by a certain logical unit, it means that the data currently stored in this physical unit includes valid data. On the contrary, if a certain physical unit is not currently mapped by any logic unit, it means that the data currently stored in this physical unit is invalid data.

The memory management circuit 51 may record the management data (also referred to as the logical to physical mapping information) describing the mapping relationship between logical units and physical units in at least one logical to physical mapping table. When the host system 11 reads data from the memory storage device 10 or writes data to the memory storage device 10, the memory management circuit 51 may access the rewritable non-volatile memory module 43 according to the information in the logical to physical mapping table.

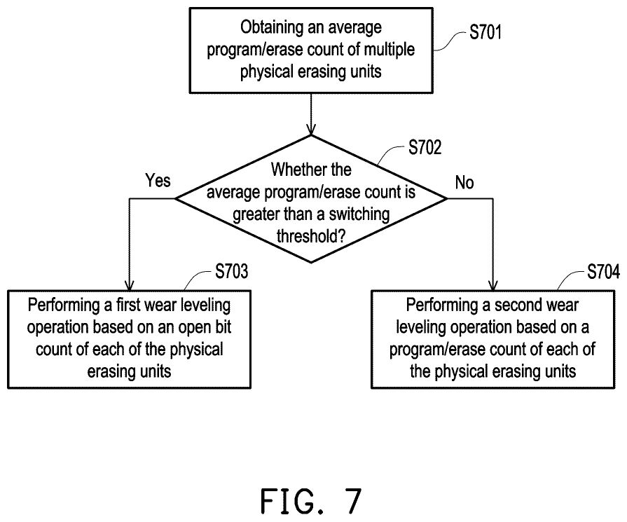

FIG. 7 is a flowchart of a wear leveling method according to an exemplary embodiment of the disclosure. Referring to FIG. 7, in step S701, the memory management circuit 51 may obtain the average program/erase count of multiple physical erasing units. For example, the memory management circuit 51 may obtain the average program/erase count of all physical erasing units in the rewritable non-volatile memory module 43. Next, in step S702, the memory management circuit 51 may determine whether the average program/erase count obtained from step S701 is greater than the switching threshold (e.g., 50k times). If the average program/erase count is greater than the switching threshold, step S703 is proceeded. On the contrary, if the average program/erase count is less than or equal to the switching threshold, step S704 is proceeded. The switching threshold may be designed by the user according to actual requirements and/or specifications of the memory storage device 10, and is not limited by the disclosure.

The traditional wear leveling method, such as exchanging a physical erasing unit with a lower program/erase count in the storage area 601 (also referred to as the source physical erasing unit) with a physical erasing unit with a higher program/erase count in the spare area 602 (also referred to as the target physical erasing unit), aim to level the program/erase counts across all physical erasing units in the rewritable non-volatile memory module 43. The wear leveling method of the disclosure involves using the open bit count as the basis for implementation to perform a wear leveling operation (i.e., a first wear leveling operation) when the average value of the program/erase count of all physical erasing units in the rewritable non-volatile memory module 43 exceeds the aforementioned switching threshold.

In step S703, the memory management circuit 51 may perform a first wear leveling operation based on the open bit count of each of the physical erasing units. When the average program/erase count is greater than the switching threshold (i.e., when the rewritable non-volatile memory module 43 is in a case of high program/erase count), the memory management circuit 51 may perform the first wear leveling operation based on the open bit count configured to indicate the degree of wear of the physical erasing units.

Specifically, the memory management circuit 51 may obtain the open bit count of each of the physical erasing units. For example, the memory management circuit 51 may perform a status read operation on each of the physical erasing units in a background mode to obtain the open bit count of each of the physical erasing units. For example, the memory management circuit 51 may, in background mode, initially perform a status read operation on a portion of the physical erasing units, and after a period of time, perform a status read operation on another portion of the physical erasing units, to obtain the open bit count for all physical erasing units. For example, the memory management circuit 51 may perform a status read operation on multiple physical erasing units at one time in the background mode to obtain the open bit count of all physical erasing units. The implementation details of the status read operation performed by the memory management circuit 51 have been described in detail in the previous embodiments and are not repeated herein.

Next, the memory management circuit 51 may determine whether there is a first physical erasing unit with an open bit count greater than a first threshold in the rewritable non-volatile memory module 43. If there is a first physical erasing unit with the open bit count greater than the first threshold, the memory management circuit 51 may perform a first wear leveling operation on the first physical erasing unit. In detail, the memory management circuit 51 may obtain the open bit count of each of the physical erasing units. Each of the open bit counts may be configured to indicate the degree of wear of its corresponding physical erasing unit. Accordingly, the memory management circuit 51 may use the first physical erasing unit (i.e., a severely worn physical erasing unit) with the open bit count greater than the first threshold as the target physical erasing unit to complete the first wear leveling operation. For example, the memory management circuit 51 may designate the first physical erasing unit with the open bit count greater than a first threshold as the target physical erasing unit. Additionally, the memory management circuit 51 may select another physical erasing unit with an open bit count less than the first threshold as the source physical erasing unit to complete the first wear leveling operation. The first threshold may be designed by the user according to actual requirements and/or specifications of the memory storage device 10, and is not limited by the disclosure.

In addition, if there is no first physical erasing unit with an open bit count greater than the first threshold, that is, the open bit count of each of the physical erasing units in the rewritable non-volatile memory module 43 is less than or equal to the first threshold, the memory management circuit 51 may not perform the first wear leveling operation first. After a period of time, the memory management circuit 51 may re-obtain the open bit count of each of the physical erasing units, and determine again whether there is a first physical erasing unit with an open bit count greater than the first threshold. This process continues until there is such a first physical erasing unit, at which point the first wear leveling operation may be performed.

On the other hand, in step S704, the memory management circuit 51 may perform a second wear leveling operation based on the program/erase count of each of the physical erasing units. When the average program/erase count is less than or equal to the switching threshold (i.e., when the rewritable non-volatile memory module 43 is in a case of low program/erase count), the memory management circuit 51 may first disregard the degree of wear of the rewritable non-volatile memory module 43 and instead utilize a second wear leveling operation based on the program/erase count.

Specifically, the memory management circuit 51 may obtain the program/erase count of each of the physical erasing units, select the source physical erasing unit and the target physical erasing unit according to the program/erase count of each of the physical erasing units, and copy the valid data in the source physical erasing unit to the target physical erasing unit to complete the second wear leveling operation.

Based on the above, the wear leveling method of the disclosure may provide a staged wear leveling operation through the average program/erase count of the rewritable non-volatile memory module 43. When the average program/erase count is greater than the switching threshold, the first wear leveling operation based on the open bit count used to indicate the degree of wear of the physical erasing unit is adopted to perform the first wear leveling operation to avoid severe wear on the rewritable non-volatile memory module 43 and extend the service life of the rewritable non-volatile memory module 43.

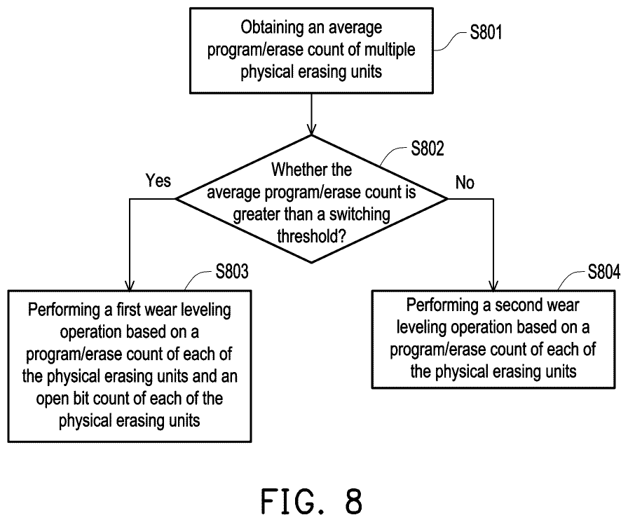

FIG. 8 is a flowchart of a wear leveling method according to an exemplary embodiment of the disclosure. Referring to FIG. 8, in step S801, the memory management circuit 51 may obtain the average program/erase count of multiple physical erasing units. In step S802, the memory management circuit 51 may determine whether the average program/erase count obtained from step S801 is greater than the switching threshold. If the average program/erase count is greater than the switching threshold, step S803 is proceeded. On the contrary, if the average program/erase count is less than or equal to the switching threshold, step S804 is proceeded.

In step S803, the memory management circuit 51 may perform a first wear leveling operation based on a program/erase count of each of the physical erasing units and an open bit count of each of the physical erasing units. Each of the open bit counts may be configured to indicate the degree of wear of its corresponding physical erasing unit. For example, the memory management circuit 51 may obtain the program/erase count and the open bit count of all physical erasing units in the rewritable non-volatile memory module 43. Next, the memory management circuit 51 may select the source physical erasing unit and the target physical erasing unit according to the program/erase count and the open bit count of all physical erasing units in the rewritable non-volatile memory module 43, and copy the valid data in the source physical erasing unit to the target physical erasing unit to complete the first wear leveling operation.

On the other hand, in step S804, the memory management circuit 51 may perform a second wear leveling operation based on the program/erase count of each of the physical erasing units. For example, the memory management circuit 51 may select the source physical erasing unit and the target physical erasing unit according to the program/erase count of all physical erasing units in the rewritable non-volatile memory module 43, and copy the valid data in the source physical erasing unit to the target physical erasing unit to complete the second wear leveling operation.

Based on the above, the wear leveling method of the disclosure may provide a staged wear leveling operation through the average program/erase count of the rewritable non-volatile memory module 43. When the average program/erase count is greater than the switching threshold, in addition to the program/erase count, the open bit count used to indicate the degree of wear of the physical erasing unit is further considered to perform the first wear leveling operation to avoid severe wear on the rewritable non-volatile memory module 43 and extend the service life of the rewritable non-volatile memory module 43.

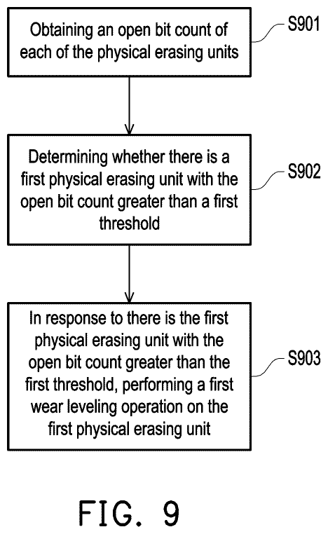

FIG. 9 is a flowchart of a wear leveling method according to an exemplary embodiment of the disclosure. Referring to FIG. 9, in step S901, the open bit count of each of the physical erasing units is obtained. In step S902, it is determined whether there is a first physical erasing unit with an open bit count greater than a first threshold. In step S903, in response to there being a first physical erasing unit with the open bit count greater than the first threshold, a first wear leveling operation is performed on the first physical erasing unit.

However, each step in FIG. 9 has been described in detail as above, and are not repeated herein. It should be noted that each of the steps in FIG. 9 may be implemented as multiple program codes or circuits, and the disclosure is not limited thereto. In addition, the method in FIG. 9 may be used in conjunction with the above-mentioned exemplary embodiments, or may be used alone, and the disclosure is not limited thereto.

To sum up, the wear leveling method, the memory storage device, and the memory control circuit unit provided by the exemplary embodiments of the disclosure may provide staged wear leveling operation. By using the open bit count as the basis for the wear leveling operation, severe wear of the rewritable non-volatile memory module may be avoided and the service life of the rewritable non-volatile memory module may be extended.

Although the disclosure has been described in detail with reference to the above exemplary embodiments, they are not intended to limit the disclosure. Those skilled in the art should understand that it is possible to make changes and modifications without departing from the spirit and scope of the disclosure. Therefore. the protection scope of the disclosure shall be defined by the following claims.

What is claimed is:

1. A wear leveling method for a rewritable non-volatile memory module, the rewritable non-volatile memory module comprising a plurality of physical erasing units, the wear leveling method comprising:
obtaining an open bit count of each of the physical erasing units;
determining whether there is a first physical erasing unit with the open bit count greater than a first threshold; and
in response to there being the first physical erasing unit with the open bit count greater than the first threshold, performing a first wear leveling operation on the first physical erasing unit.

2. The wear leveling method according to claim 1, wherein obtaining the open bit count of each of the physical erasing units comprises:
performing a status read operation on each of the physical erasing units to obtain the open bit count.

3. The wear leveling method according to claim 2, wherein performing the status read operation further comprises:
applying a read voltage to a plurality of memory cells in each of the physical erasing units in a writing state to obtain the open bit count.

4. The wear leveling method according to claim 2, wherein an error detecting and correcting operation is not performed during a process of performing the status read operation.

5. The wear leveling method according to claim 1, further comprising:
obtaining an average program/erase count of the physical erasing units;
determining whether the average program/erase count is greater than a switching threshold; and
in response to the average program/erase count not being greater than the switching threshold, performing a second wear leveling operation based on a program/erase count of each of the physical erasing units.

6. The wear leveling method according to claim 5, further comprising:
in response to the average program/erase count being greater than the switching threshold, performing the first wear leveling operation based on the open bit count of each of the physical erasing units.

7. The wear leveling method according to claim 5, further comprising:
in response to the average program/erase count being greater than the switching threshold, performing the first wear leveling operation based on the program/erase count of each of the physical erasing units and the open bit count of each of the physical erasing units.

8. The wear leveling method according to claim 1, wherein the open bit count is configured to indicate a degree of wear of each of the physical erasing units.

9. The wear leveling method according to claim 1, further comprising:
in response to a number of the physical erasing units with the open bit count exceeding a warning threshold being greater than a threshold, outputting a warning signal.

10. A memory storage device, comprising:
a connection interface unit, configured to couple to a host system;
a rewritable non-volatile memory module, wherein the rewritable non-volatile memory module comprises a plurality of physical erasing units; and
a memory control circuit unit, coupled to the connection interface unit and the rewritable non-volatile memory module,
wherein the memory control circuit unit is configured to:
obtain an open bit count of each of the physical erasing units;
determine whether there is a first physical erasing unit with the open bit count greater than a first threshold; and
in response to there being the first physical erasing unit with the open bit count greater than the first threshold, perform a first wear leveling operation on the first physical erasing unit.

11. The memory storage device according to claim 10, wherein the memory control circuit unit is further configured to:
perform a status read operation on each of the physical erasing units to obtain the open bit count.

12. The memory storage device according to claim 11, wherein the memory control circuit unit is further configured to:
apply a read voltage to a plurality of memory cells in each of the physical erasing units in a writing state to obtain the open bit count.

13. The memory storage device according to claim 11, wherein an error detecting and correcting operation is not performed during a process of the memory control circuit unit performing the status reading operation.

14. The memory storage device according to claim 10, wherein the memory control circuit unit is further configured to:
obtain an average program/erase count of the physical erasing units;
determine whether the average program/erase count is greater than a switching threshold; and
in response to the average program/erase count not being greater than the switching threshold, perform a second wear leveling operation based on a program/erase count of each of the physical erasing units.

15. The memory storage device according to claim 14, wherein the memory control circuit unit is further configured to:
in response to the average program/erase count being greater than the switching threshold, perform the first wear leveling operation based on the open bit count of each of the physical erasing units.

16. The memory storage device according to claim 14, wherein the memory control circuit unit is further configured to:
in response to the average program/erase count being greater than the switching threshold, perform the first wear leveling operation based on the program/erase count of each of the physical erasing units and the open bit count of each of the physical erasing units.

17. The memory storage device according to claim 10, wherein the open bit count is configured to indicate a degree of wear of each of the physical erasing units.

18. The memory storage device according to claim 10, wherein the memory control circuit unit is further configured to:
in response to a number of the physical erasing units with the open bit count exceeding a warning threshold being greater than a threshold, output a warning signal.

19. A memory control circuit unit for controlling a rewritable non-volatile memory module, wherein the rewritable non-volatile memory module comprises a plurality of physical erasing units, and the memory control circuit unit comprises:
a host interface, configured to couple to a host system;
a memory interface, configured to couple to the rewritable non-volatile memory module;
an error detecting and correcting circuit; and
a memory management circuit, coupled to the host interface, the memory interface, and the error detecting and correcting circuit,
wherein the memory management circuit is configured to:
obtain an open bit count of each of the physical erasing units;
determine whether there is a first physical erasing unit with the open bit count greater than a first threshold; and
in response to there being the first physical erasing unit with the open bit count greater than the first threshold, perform a first wear leveling operation on the first physical erasing unit.

20. The memory control circuit unit according to claim 19, wherein the memory management circuit is further configured to:
perform a status read operation on each of the physical erasing units to obtain the open bit count.

21. The memory control circuit unit according to claim 20, wherein the memory management circuit is further configured to:
apply a read voltage to a plurality of memory cells in each of the physical erasing units in a writing state to obtain the open bit count.

22. The memory control circuit unit according to claim 20, wherein the error detecting and correcting circuit does not perform an error detecting and correcting operation during a process of the memory management circuit performing the status read operation.

23. The memory control circuit unit according to claim 19, wherein the memory management circuit is further configured to:
obtain an average program/erase count of the physical erasing units;
determine whether the average program/erase count is greater than a switching threshold; and
in response to the average program/erase count not being greater than the switching threshold, perform a second wear leveling operation based on a program/erase count of each of the physical erasing units.

24. The memory control circuit unit according to claim 23, wherein the memory management circuit is further configured to:
in response to the average program/erase count being greater than the switching threshold, perform the first wear leveling operation based on the open bit count of each of the physical erasing units.

25. The memory control circuit unit according to claim 23, wherein the memory management circuit is further configured to:
in response to the average program/erase count being greater than the switching threshold, perform the first wear leveling operation based on the program/erase count of each of the physical erasing units and the open bit count of each of the physical erasing units.

26. The memory control circuit unit according to claim 19, wherein the open bit count is configured to indicate a degree of wear of each of the physical erasing units.

27. The memory control circuit unit according to claim 19, wherein the memory management circuit is further configured to:
in response to a number of the physical erasing units with the open bit count exceeding a warning threshold being greater than a threshold, output a warning signal.
